(19) United States
(12) Patent Application Publication
(10) Pub. No.: US 2026/0032821 A1
(43) Pub. Date: Jan. 29, 2026

(54) 3D Printing Lattice Structure for Shock-Thermal Foam or Fixture Application

(71) Applicant: Apple Inc., Cupertino, CA (US)

(72) Inventors: Huili Xu, San Jose, CA (US); Yaqun Zhu, Los Gatos, CA (US); Wyeman Chen, Newark, CA (US)

(21) Appl. No.: 18/783,212

(22) Filed: Jul. 24, 2024

(51) Int. Cl. H05K 1/18; H05K 1/14

(52) U.S. Cl. CPC H05K 1/181; H05K 1/144; H05K 2201/042

(57) ABSTRACT

An electronic device may include a first circuit board coupled to a first set of components, a second circuit board coupled to a second set of components, and a three-dimensional (3D) printed insert disposed between the first circuit board and the second circuit board.

### BACKGROUND

The present disclosure relates generally to electronic devices, and more particularly, to a three-dimensional printed lattice structure to provide support or cushioning to one or more components within the electronic devices.

Electronic devices often include one or more components to present visual representations of information (e.g., text, still images, video). For example, such electronic devices may include computers, mobile phones, portable media devices, virtual reality headsets, and vehicle dashboards, among other things. To operate, the electronic devices may include one or more circuit boards coupled to respective components, such as resistors, transistors, systems-on-chips, and so on. When manufacturing the electronic device, the circuit board and/or the one or more components may undergo a lamination process that applies a film to the circuit board or the one or more components. The film may exert a stress or pressure onto the circuit board or the one or more components, which may result in board deformation (e.g., bow, bend) or component cracking.

During operation of the electronic device, the circuit boards or the one or more components may generate heat. Additionally or alternatively, the circuit boards or the one or more components may experience stress if the electronic device is dropped or hit against a surface. To dissipate heat or reduced stress experienced by the circuit board or the one or more components, the electronic device may include a layer of thermal shock foam (e.g., gel). The thermal shock foam may be difficult to evenly apply since the one or more components may be different shapes or sizes.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

The present disclosure generally relates to an electronic device. The electronic device may include one or more circuit boards coupled with respective components. During manufacturing of the electronic device, the circuit board and the one or more components may undergo numerous manufacturing operations that exert force against the components. For example, a lamination process or film molding process may apply a film to the circuit board and/or the one or more components. When applying the film, the film may exert a stress and/or a pressure onto the circuit board and the one or more components. For example, the stress may deform the circuit board and stress the components on the second side. To distribute the stress and/or reduce an amount of stress, the circuit board and/or the one or more components may be coupled to a support structure. The support structure may couple to the second surface of the circuit board and receive (e.g., interface with) the one or more components. In certain instances, the components may include different attributes, such as different shapes, sizes, and/or stress thresholds. It may be challenging for the support structure to provide adequate support to all of the components due to the different attributes of the components. As such, creating a support structure to provide support (e.g., mechanical support, structural support) customized to each component coupled to the circuit board and/or the circuit board may be difficult. Without adequate support, the circuit board may deform and/or the one or more components may crack during the lamination process.

In certain instances, the electronic device may be designed to include two or more circuit boards in a stacked configuration. Between the stacked circuit boards, the electronic device may include gel layer or foam layer (e.g., thermal shock foam/gel layer) to dissipate heat from and/or provide support to the circuit boards and their respective components. For example, the gel layer may be applied to a first circuit board and then coupled to a second circuit board. In certain instances, the components may be of different shapes and/or sizes, which may make evenly applying the gel layer or foam layer may be difficult. Additionally or alternatively, the gel layer or foam layer may degrade over time due to heat dissipated by the components during operation. Thus, improvements for an insert between two or more circuit boards for dissipating heat and/or providing support to the one or more components during operation of the electronic device may be desired.

The present disclosure provides techniques for creating a support structure that couples to and/or provides support for the circuit board and one or more components during a manufacturing process (e.g., lamination process, molding process, hot bar process) and an insert coupled to two circuit boards when positioned inside an electronic device. First, the electronic device may include a circuit board and one or more components of the electronic device coupled to the support structure during the manufacturing process and/or prior to assembly of the electronic device. The support structure may be modulated to provide customized support to each component. For example, the support structure may include one or more portions with different properties to provide customized support to each component of the circuit board. The properties may include a stiffness, a density, a hardness, a porosity, and so on. The properties may be determined based on a stress threshold of the component interfacing with a respective portion of the support structure. As such, the support structure may distribute stress exerted onto the circuit board and/or the one or more components by the film, thereby reducing the amount of stress applied to circuit board and/or the components. Accordingly, the support structure may provide sufficient support to the component without overstressing the component.

The electronic device may include an insert positioned between a first circuit board and a second board to dissipate heat generated by the components within the electronic device and/or provide support to the circuit boards and the respective components coupled to each of the circuit boards within the electronic device. For example, the insert may be made from a material that absorbs heat generated by the components and directs the heat in a direction away from the component. Additionally or alternatively, the insert may be modulated to provide customized support for each component. For example, the insert may include a first portion with a first set of properties to support a first component and a second portion with a second set of properties to support a second component, where the first set of properties may be different from the second set of properties. As such, the insert may dissipate heat from the components during operation of the electronic device and/or provide support to the circuit board and/or the one or more components.

### BRIEF DESCRIPTION OF THE DRAWINGS

Various aspects of this disclosure may be better understood upon reading the following detailed description and upon reference to the drawings in which:

FIG. 1 is a block diagram of an electronic device that includes an electronic display, in accordance with an embodiment;

FIG. 2 is an example of the electronic device of FIG. 1 in the form of a handheld device, in accordance with an embodiment;

FIG. 3 is another example of the electronic device of FIG. 1 in the form of a tablet device, in accordance with an embodiment;

FIG. 4 is another example of the electronic device of FIG. 1 in the form of a computer, in accordance with an embodiment;

FIG. 5 is another example of the electronic device of FIG. 1 in the form of a watch, in accordance with an embodiment;

FIG. 6 is another example of the electronic device of FIG. 1 in the form of a computer, in accordance with an embodiment;

FIG. 7 is a block diagram of a component of the electronic device of FIG. 1 supported by a support structure, in accordance with an embodiment;

FIG. 8 is a schematic diagram of an embodiment of a pattern for the support structure, in accordance with an embodiment;

FIG. 9 is a schematic diagram of another embodiment of a pattern for the support structure, in accordance with an embodiment;

FIG. 10 is a schematic diagram of another embodiment of a pattern for the support structure, in accordance with an embodiment;

FIG. 11 is a flowchart of an example process for manufacturing the electronic device of FIG. 1 with support by a support structure, in accordance with an embodiment;

FIG. 12 is a flowchart of an example process for creating support structure for the electronic device of FIG. 1, in accordance with an embodiment;

FIG. 13 is a flowchart of an example process for laminating a component of the electronic device of FIG. 1 with support by the support structure of FIG. 11, in accordance with an embodiment;

FIG. 14 is a block diagram of components of the electronic device of FIG. 1, in accordance with an embodiment;

FIG. 15 is a flowchart of an example process for creating a support structure for the electronic device of FIG. 1, in accordance with an embodiment; and

FIG. 16 is a flowchart of an example process for assembling the electronic device of FIG. 1 with the support structure of FIG. 14, in accordance with an embodiment.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “including” and “having” are intended to be inclusive and mean that there may be additional elements other than the listed elements. Additionally, it should be understood that references to “one embodiment,” “an embodiment,” “embodiments,” and “some embodiments” of the present disclosure are not intended to be interpreted as excluding the existence of additional embodiments that also incorporate the recited features.

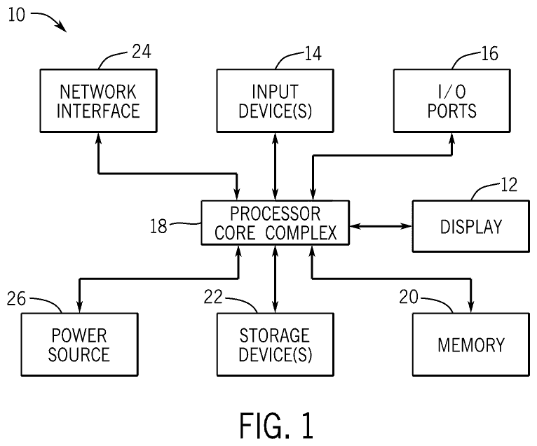

With the foregoing in mind, FIG. 1 is an example electronic device 10 with an electronic display 12 having independently controlled color component illuminators (e.g., projectors, backlights). As described in more detail below, the electronic device 10 may be any suitable electronic device, such as a computer, a mobile phone, a portable media device, a tablet, a television, a virtual-reality headset, a wearable device such as a watch, a vehicle dashboard, or the like. Thus, it should be noted that FIG. 1 is merely one example of a particular implementation and is intended to illustrate the types of components that may be present in an electronic device 10.

The electronic device 10 may include one or more electronic displays 12, input devices 14, input/output (I/O) ports 16, a processor core complex 18 having one or more processors or processor cores, local memory 20, a main memory storage device 22, a network interface 24, a power source 26, and image processing circuitry 28. The various components described in FIG. 1 may include hardware elements (e.g., circuitry), software elements (e.g., a tangible, non-transitory computer-readable medium storing instructions), or a combination of both hardware and software elements. As should be appreciated, the various components may be combined into fewer components or separated into additional components. For example, the local memory 20 and the main memory storage device 22 may be included in a single component. Moreover, the image processing circuitry 28 (e.g., a graphics processing unit, a display image processing pipeline) may be included in the processor core complex 18 or be implemented separately.

The electronic display 12 may display a graphical user interface (GUI) (e.g., of an operating system or computer program), an application interface, text, a still image, and/or video content. The electronic display 12 may include a display panel with one or more display pixels to facilitate displaying images.

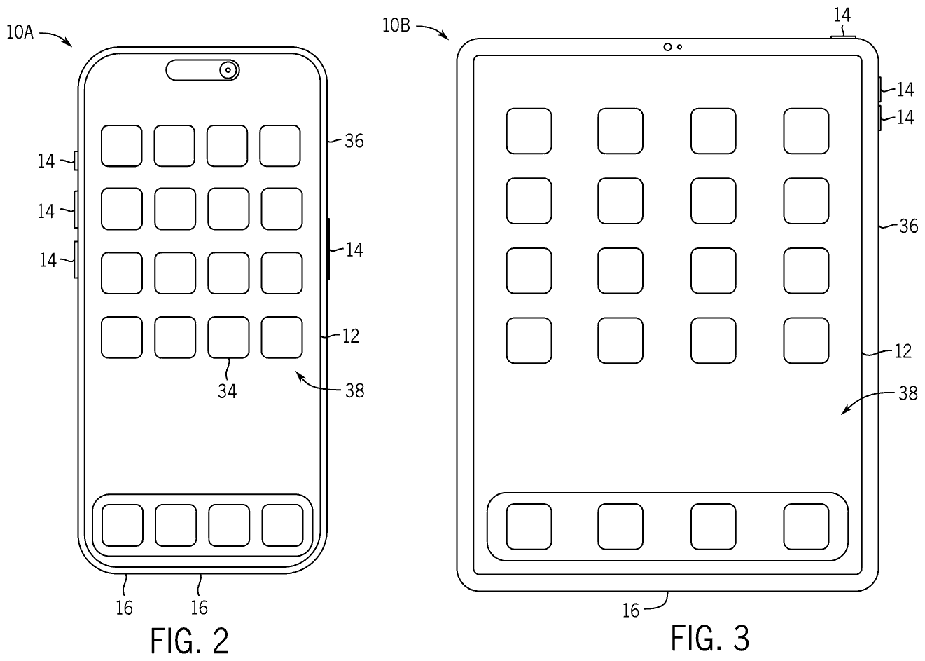

The electronic device 10 may be any suitable electronic device. To help illustrate, one example of a suitable electronic device 10, specifically a handheld device 10A, is shown in FIG. 2. In some embodiments, the handheld device 10A may be a portable phone, a media player, a personal data organizer, a handheld game platform, and/or the like. For illustrative purposes, the handheld device 10A may be a smartphone, such as an iPhone® model available from Apple Inc.

The handheld device 10A may include an enclosure 36 (e.g., housing) to, protect interior components from physical damage and/or shield them from electromagnetic interference. The housing 36 may surround, at least partially, the electronic display 12. In the depicted embodiment, the electronic display 12 is displaying a graphical user interface (GUI) 38 having an array of icons 34. By way of example, when an icon 34 is selected either by an input device 14 or a touch-sensing component of the electronic display 12, an application program may launch.

Input devices 14 may be accessed through openings in the housing 36. Moreover, the input devices 14 may enable a user to interact with the handheld device 10A. For example, the input devices 14 may enable the user to activate or deactivate the handheld device 10A, navigate a user interface to a home screen, navigate a user interface to a user-configurable application screen, activate a voice-recognition feature, provide volume control, and/or toggle between vibrate and ring modes. Moreover, the I/O ports 16 may also open through the housing 36. Additionally, the electronic device may include one or more cameras to capture pictures or video. In some embodiments, a camera may be used in conjunction with a virtual reality or augmented reality visualization on the electronic display 12.

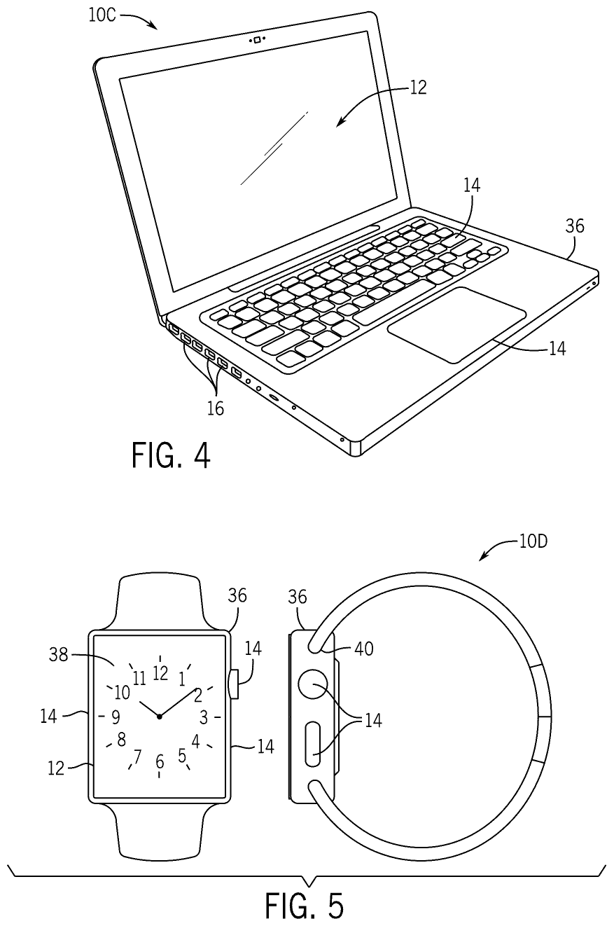

Another example of a suitable electronic device 10, specifically a tablet device 10B, is shown in FIG. 3. The tablet device 10B may be any iPad® model available from Apple Inc. A further example of a suitable electronic device 10, specifically a computer 10C (e.g., notebook computer), is shown in FIG. 4. By way of example, the computer 10C may be any MacBook® model available from Apple Inc. Another example of a suitable electronic device 10 (e.g., a worn device), specifically a watch 10D, is shown in FIG. 5. By way of example, the watch 10D may be any Apple Watch® model available from Apple Inc. As depicted, the tablet device 10B, the computer 10C, and the watch 10D each also includes an electronic display 12, input devices 14, I/O ports 16, and an enclosure 30. The electronic display 12 may display a GUI 32. Here, the GUI 32 shows a visualization of a clock. When the visualization is selected either by the input device 14 or a touch-sensing component of the electronic display 12, an application program may launch, such as to transition the GUI 32 to presenting the icons 34 discussed with respect to FIGS. 2 and 3.

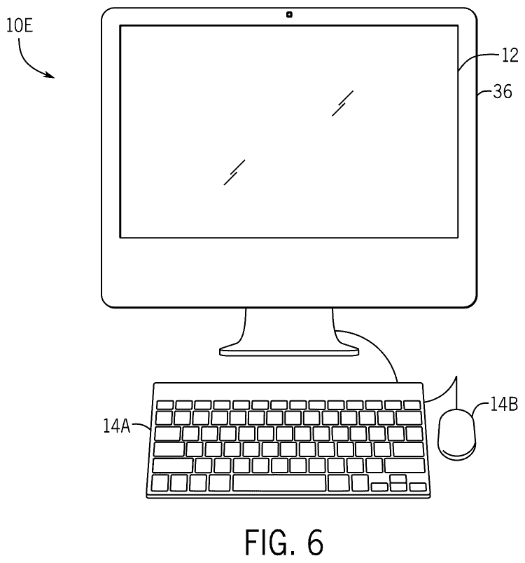

Turning to FIG. 6, a computer 10E may represent another embodiment of the electronic device 10 of FIG. 1. The computer 10E may be any suitable computer, such as a desktop computer or a server, but may also be a standalone media player or video gaming machine. By way of example, the computer 10E may be an iMac® or other device by Apple Inc. of Cupertino, California. It should be noted that the computer 10E may also represent a personal computer (PC) by another manufacturer. A similar enclosure 30 may be provided to protect and enclose internal components of the computer 10E, such as the electronic display 12. In certain embodiments, a user of the computer 10E may interact with the computer 10E using various peripheral input devices 14, such as a keyboard 14A or mouse 14B, which may connect to the computer 10E.

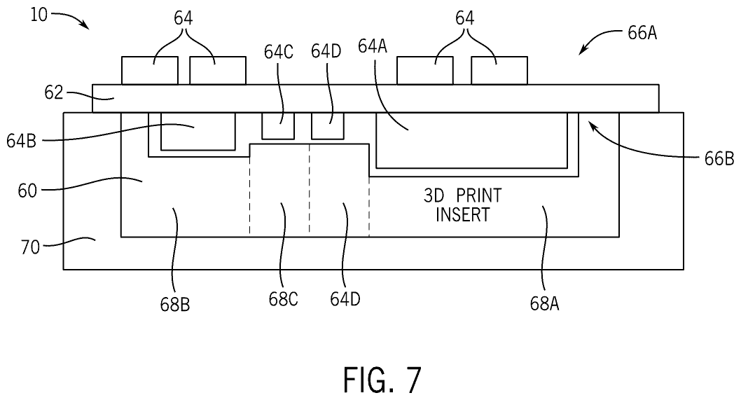

FIG. 7 is a block diagram of one or more components of the electronic device 10 coupled to a support structure 60. For example, the electronic device 10 may include a circuit board 62 with one or more components 64. The one or more components 64 may include such as transistors, resistors, capacitors, power sources, system-on-chips, baseband processors, and so on. The components 64 may respectively couple to a first surface 66A of the circuit board 62, a second surface 66B of the circuit board 62, or both. It may be understood that the circuit board 62 may be coupled to any suitable number and/or any suitable types of components 64. Each component 64 may include a set of attributes, such as a stress threshold, a shape, a size, a functionality and so on. For example, the stress threshold of a component may be determined based on a size of the component 64 and/or a location of the component 64 with respect to the circuit board 62. For example, larger and/or thicker components may include a higher stress threshold in comparison to smaller and/or thinner components. In another example, a component 64 positioned at a location of the circuit board 62 prone to bending may include a lower stress threshold in comparison to a second component 64 positioned at a second location of the circuit board 62 not prone to bending. The circuit board 62 may be thicker at the second location in comparison to the first location. In another example, the circuit board 62 may include portions that jut out, narrow extensions, and the like, which may be flexible and/or bendable. A component 64 located on a narrow extension may include a higher stress threshold in comparison to a component 64 located on an interior location of the circuit board 62. As such, support provided to each component 64 may be different based on the attributes of the component 64.

During manufacturing and/or prior to assembly of the electronic device 10, the circuit board 62 and/or the one or more components 64 may undergo a manufacturing process (e.g., a lamination process, a film molding process, a hot bar process, a Surface Mount Technology (SMT) process) that results in a force being exerted on a surface (e.g., the first surface 66A, the second surface 66B) of the circuit board 62. For example, a lamination process may apply a film to a surface (e.g., the first surface 66A, the second surface 66B) of the circuit board 62. If the film is applied to the first surface 66A of the circuit board 62 and/or the one or more components 64, the process may apply a stress to the first surface 66A of the circuit board 62, deform the circuit board 62, and stress component on the second surface 66B of the circuit board 62. As such, components 64 on coupled to the second surface 66B of the circuit board 62 may experience stress exerted by the process. To reduce an amount of stress experienced by the circuit board 62 and/or the components 64, a support structure 60 may couple to the circuit board 62 and/or the one or more components 64 may be coupled to a support structure 60. The support structure 60 may provide support (e.g., mechanical support, structural support) to and/or distribute stress applied to the circuit board 62 and/or the one or more components 64 during the lamination process, thereby reducing an amount of stress and/or pressure experienced by the components 64. For example, the support structure 60 may couple to and/or interface with a second surface 66B of the circuit board 62 and/or the one or more components 64 coupled to the second surface 66B.

The support provided by the support structure 60 may be modulated based on attributes of the components 64. For example, the support structure 60 may provide a customized (e.g., pre-determined, individualized, tailored) amount of support and/or cushioning to the components 64 based on a stress threshold of the respective component 64 and/or a position of the respective component 64 on the circuit board. The support structure 60 may include one or more portions 68 with different properties to provide the customized support to the components 64. For example, the support structure 60 may include a first portion 68A with a first set of properties (e.g., material properties) to support a first component 64A, a second portion 68B with a second set of properties to support a second component 64B, a third portion 68C with a third set of properties to support a third component 64C, and/or a fourth portion 68D with a fourth set of properties to support a fourth component 64D. The properties may include a pattern (e.g., lattice structure), a type of material, a height, a width, a length, a stiffness, a density, a conductivity, a porosity, and the like. The properties may be determined for each portion 68 of the support structure 60 to provide customized support for the components 64 on the second surface 66B of the circuit board 62. For example, the patterns may include different repeating units (e.g., geometries), such as square, rod, rectangular, triangular, circular, S-shaped, mixed morphology, and so on. The arrangement of the repeating units, such as a density of the repeating units, may impact a load-bearing capacity of the portion 68. For example, a portion 68 formed by rods may provide distribute a load (e.g., stress) in a linear direction while a portion 68 formed by S-shapes may distribute the load in different directions. In another example, a portion 68 that may be more densely packed with the geometries may be stiffer and less compressible in comparison to a portion 68 that may be less densely packed.

The material used to form a respective portion 68 of the support structure 60 may include any suitable material for supporting the components 64 and/or the circuit board 62. For example, the materials may include plastics and polymers (e.g., polylactic acid (PLA), polyurethanes (PU), acrylonitrile butadiene styrene (ABS)), resins, metals (e.g., graphite, steel silicon oxide, alumina oxide), composites (e.g., carbon fiber reinforced polymers, glass fiber reinforced polymers), ceramics, and the like. The materials may include respective properties, such as a hardness, a toughness, an elasticity, a tensile strength, a modulation, and the like, which may be adjust the stiffness of the respective portion 68. As such, a material for the portion 68 may be selected based on the material properties of the material and the attributes of the component 64. To modulate the support structure 60 for example, the first portion 68A may be made from a first material with a first set of properties and a second portion 68B may be made from a second material with a second set of properties. Additionally or alternatively, the first portion 68A may be made from a first material and designed to include a first set of properties and the second portion 68B may be made from the first material and designed to include a second set of properties. For example, the first portion 68A may include a first density to increase a stiffness and provide more support, while the second portion 68B may include a second density to increase porosity and decrease support. The first density may be greater than the second density. In this way, the portions 68 of the support structure 60 may provide different amounts of support to the circuit board 62 and/or the one or more components 64.

The size of the support structure 60 may be modulated to accommodate the attributes of the components 64. For example, a height, a width, and/or a length of a respective portion 68 may be determined based on a size of the component 64. As such, the portion 68 may receive and/or interface with a respective component 64. For example, a height of the first portion 68A may be adjusted based on a height of the first component 64A that interfaces with the first portion 68A. As illustrated, a height of the first portion 68A may be less than a height of the second portion 68B since a height of the first component 64A may be greater than a height of the second component 64B. Additionally or alternatively, each portion 68 may include a recession with a length and a width to receive the component 64. For example, the first portion 68A may include a first recession that fits to the first component 64A, the second portion 68B may include a second recession that fits to the second component 64B, the third portion 68C may include a third recession that fits to the third component 64C, and/or the fourth portion 68D may include a fourth recession that fits to the fourth component 64D. As illustrated, a length and/or a width of the first portion 68A may be greater than a length and/or a width of the third portion 68C and/or the fourth portion 68D since the length and/or the width of the first component 64A may be greater than a respective length and/or a respective width of the third component 64C and/or the fourth component 64D. Additionally or alternatively, a shape of the recessions may be adjusted based on a shape of the component 64. For example, the recessions may include a circular shape, a rectangular shape, a trapezoidal shape, an oval shape, and so on. As such, a shape and/or a size of the portions 68 may be modulated to receive (e.g., couple to, interface with) the component 64, which may improve support provided to the components 64 by the support structure 60.

By way of specific example, the support structure 60 may support the circuit board 62 during a hot bar process that applies heat to the circuit board 62 through the support structure 60. To conduct the heat, the support structure 60 may include thermoconductive material. For example, the support structure 60 may include graphite and/or metal oriented in a vertical direction to conduct heat from the hot bar process and direct the heat vertically towards the circuit board 62. Based on a heat threshold of each component 64, the portions 68 of the support structure 60 may include respective properties to conduct the heat. For example, a first portion 68A of the support structure 60 may include densely packed microstructures to conduct more heat in comparison to a second portion 68B of the support structure 60 that may include a porous microstructure. As such, the support structure 60 may be modulated based on the attributes of the components 64.

In certain instances, the support structure 60 may be three-dimensional (3D) printed, which may save time and/or resources. Since 3D printing produces complex designs and/or geometries in a single manufacturing step and/or provides for customization and/or on-demand manufacturing, time used to produce the support structure 60 may be reduced in comparison to traditional manufacturing methods. Moreover, the support structure 69 may be custom created and/or designed for different circuit boards based on the components 64 coupled to the circuit board 62 and/or the attributes of the components 64. For example, the support structure 60 may be 3D printed with different materials and/or different lattice structures that provide a respective property to a respective portion 68 of the support structure. In another example, the support structure 60 may include different portions 68 with respective densities, microstructures, and the like. The portions 68 of the support structure 60 may be immediately bonded during the 3D printing process. In this way, the support structure 60 may include one or more portions 68 with a respective set of properties customized (e.g., modulated) to support a respective component 64. Additionally or alternatively, a size of a portion of the support structure 60 may be varied based on a shape and/or a size of the component 64 interfacing with the support structure 60. In other examples, the support structure may be made from a molding process, casting process, and the like. Although the illustrative example includes four portions 68, it may be understood that the support structure 60 may include any suitable number of portions 68 with any suitable properties to provide support to any suitable number and/or suitable type of components 64.

In certain instances, the support structure 60 may couple to a carrier 70 that may couple to the support structure 60. The carrier 70 may be used to for moving the support structure 60, the circuit board 62, and/or the components 64 from a first location to a second location. The carrier 70 may also provide support to the circuit board 62 and/or the components 64 during the process and/or prior to assembling the electronic device 10. The carrier 70 may be made from any suitable material to support the support structure 60, the circuit board 62, and/or the components 64. Additionally or alternatively, the carrier 70 may be any suitable shape and/or size to interface with the support structure 60.

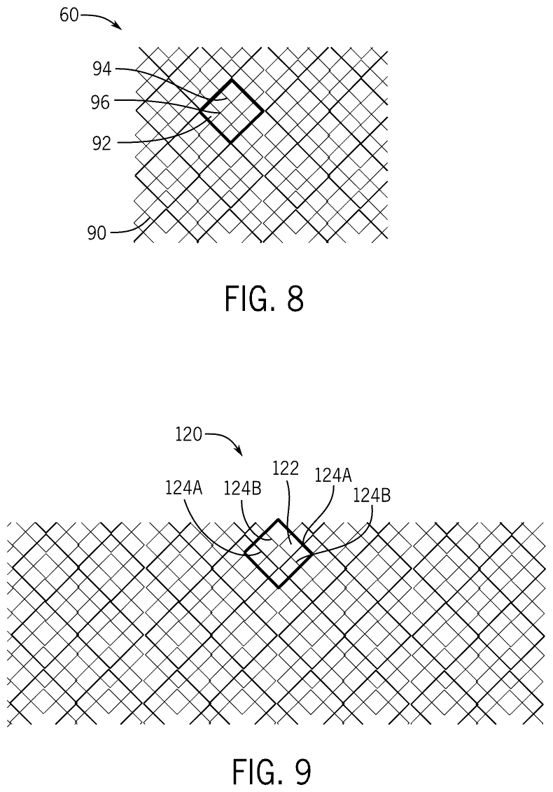

FIG. 8 is a schematic diagram of an embodiment of a pattern 90 used in a portion 68 of the support structure 60. The pattern 90 may include microstructures (e.g., cells, repeating unit, lattice nodes) 92 that repeats throughout the portion 68 to form a lattice structure (e.g., a pattern). As illustrated, the microstructure 92 may be a square. The square microstructure 92 may include struts 94 and nodes 96 that form a grid pattern resembling a mesh of squares. Additionally or alternatively, the square microstructures 92 may couple and/or overlap at respective nodes 96 to form the pattern 90. The struts 94 and the nodes 96 may be distributed throughout the pattern 90 at equal distances, which may support the circuit board 62 and/or the one or more components 64 by evenly distributing the forces (e.g., axial force, longitudinal force, downward force) from the circuit board 62 and/or the one or more components 64 during the process.

In certain instances, the properties of the pattern 90 may be adjusted by adjusting the properties of the microstructure 92. The properties of the pattern 92 may include a length of the struts 94, a thickness of the struts 94, a number of struts 94, and so on. The properties of the pattern 90 may include a density of the microstructures 92, a porosity of the microstructures 92, a direction of the microstructures 92, a size of the microstructures 92, and so on. For example, increasing a size and/or a thickness of the struts 94 may increase a size and/or a density of the microstructure 92, which may increase a stiffness of the microstructure 92 and/or support provided by the microstructure 92. By increasing the stiffness of the microstructure 92, the portion 68 of the support structure 60 may provide increased support to the circuit board 62 and/or the components 64. Additionally or alternatively, a density of the pattern 90 may be adjusted by adjusting the size of the microstructure 92 and/or a material used for the microstructure 92. In this way, portions 68 of the support structure 60 may be customized to provide support the circuit board 62 and/or the components 64.

FIG. 9 is a schematic diagram of another embodiment of a pattern 120 used in a portion 68 of the support structure 60. As illustrated, the pattern 120 of FIG. 9 is substantially similar to the pattern 90 of FIG. 8 except the pattern 120 of FIG. 9 includes a mix morphology. The pattern 120 includes a microstructure 122 formed by a first set of struts 124A with a first set of properties and a second set of struts 124B with a second set of properties. For example, as illustrated, the first set of struts 124A may be thicker than the second set of struts 124B, which may increase a density and/or a stiffness of the pattern 120. For example, the pattern 120 may provide increased support to the circuit board 62 and/or the components 64 in comparison to the pattern 90 described with respect to FIG. 8. In another example, the first set of struts 124A may be made from a first material and the second set of struts 124B may be made from a second material that may be different from the first material. By varying the properties of the struts 124, the properties of the pattern 120 and/or the portion 68 incorporating the pattern 120 may be customized to support the circuit board 62 and/or the components 64.

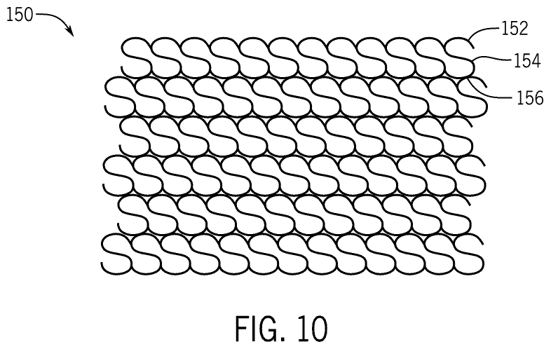

FIG. 10 is a schematic diagram of another embodiment of a pattern 150 used in a portion 68 of the support structure 60. As illustrated, the pattern 150 may include a microstructure 152 with an S-shape microstructure 152 that repeats throughout the pattern 150. The S-shape microstructure 152 may be formed by a strut 154 with curvatures to form the shape of an S. The struts 154 may respectively couple at nodes 156 to form the pattern 150. The S-shape microstructure 152 may increase flexibility and/or compression due to the curvature of the microstructure 152. Additionally or alternatively, the S-shape microstructure 152 may act as springs and/or damper, which may improve energy absorption, improve cushioning, and the like. The properties of the pattern 150 may be adjusted by adjusting a thickness (e.g., width) of the microstructure 152 and/or a length of the microstructure 152. Additionally or alternatively, the properties of the pattern 150 may be adjusted by adjusting a density of the microstructures 152 within the pattern 150. For example, packing the microstructures 152 closer together may increase the density in comparison to packing the microstructures 152 loosely. As such, the portions 68 may be customized to provide support to the circuit board 62 and/or the components 64.

It may be understood that the portion 68 may be constructed with a pattern using any suitable type of microstructure. For example, the pattern may include two or more microstructures that include different shapes, sizes, materials, and so on. For example, the pattern may include S-shape microstructures and rod microstructures, thereby combining two different microstructures. In another example, the pattern may include a first square microstructure with a first size, a second square microstructure with a second size, and/or a third square microstructure with a third size. Additionally or alternatively, the first square microstructure may be made from a first material and the second and third square microstructure may be made from a second material. Indeed, the shape, the size, and/or the material of the microstructure may be determined based the component 64, such as an amount of support to provide to the component 64 during the process.

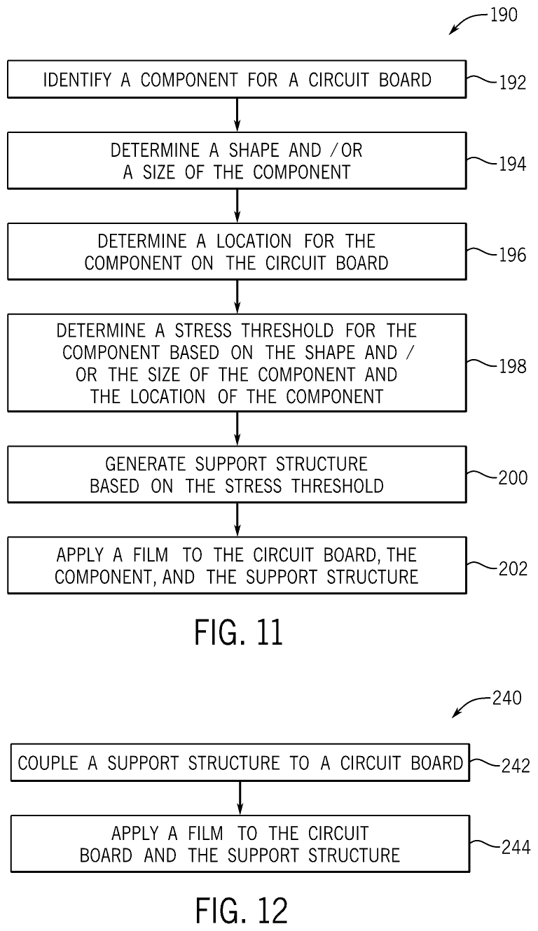

FIG. 11 is a flowchart of an example process 160 for manufacturing the electronic device 10 with support by the support structure 60. For example, the electronic device 10 may include one or more circuit boards 62 that may undergo a manufacturing process (e.g., operation). During the manufacturing process, a force may be exerted onto the circuit board 62 and/or components 64 of the circuit board 62. To reduce the amount of force experienced by the circuit board 62 and/or the components 64, a support structure 60 may be coupled to the circuit board 62 and/or the components 64. The support structure 60 may distribute the force, thereby reducing the amount of force experienced by the circuit board 62 and/or the components 64. As such, board deformation and/or component damage may be reduced.

At block 162, a circuit board 62 may be received. For example, a circuit board 62 for the electronic device 10 may be received at a manufacturing line. The circuit board 62 may include one or more components 64 coupled to a first side and/or the second side.

At block 164, a 3D printed support structure 60 may be provided around components 64 on one side of the circuit board 62. The support structure 60 may couple to either the first side or the second side of the circuit board 62. The support structure 60 may interface with the components 64 to provide support to the components 64 and/or the circuit board 62. For example, the support structure 60 may include modulated portions 68 with properties customized to each component 64 to provide support and/or distribute forces during the manufacturing process.

At block 166, operations may be performed to the circuit board 62 while the circuit board 62 may be supported. For example, the circuit board 62 and the support structure 60 may undergo a lamination process and a film may be applied to one side of the circuit board 62. The support structure 60 may support the opposite side of the circuit board 62 and absorb an amount of force applied from the film. In other examples, the circuit board 62 and the support structure 60 may undergo a hot bar process, a film molding process, and the like. By absorbing and/or distributing an amount of stress, the amount of stress experienced by the circuit board 62 and/or the components 64 may be reduced. As such, board deformation and/or component damage may be reduced or elimination.

While the process of FIG. 11 is described using process blocks in a specific sequence, it should be understood that the present disclosure contemplates that the described process blocks may be performed in different sequences than the sequence illustrated, and certain described process blocks may be skipped or not performed altogether.

FIG. 12 is a flowchart of an example process 190 for creating support structure 60 to support the electronic device 10 during a manufacturing process. During manufacturing of the electronic device 10, for example, a circuit board 62 of the electronic device 10 along with one or more components 64 coupled to the circuit board 62 may undergo a manufacturing process that may exert a force on the circuit board 62 and/or the one or more components 64. During a lamination process, for example, a film may be applied to a first surface 66A of the circuit board 62, which may also apply a stress and/or a pressure to the circuit board 62 and the components 64 coupled to the circuit board 62. The stress and/or the pressure may be transferred from the first surface 66A to the second surface 66B. To distribute the stress exerted by the film, the circuit board 62 and/or the components 64 may be coupled to a support structure 60. For example, the support structure 60 may absorb a portion of the stress, thereby reducing an amount of stress experienced by the circuit board 62 and/or the components 64 during the manufacturing. As such, the support structure 60 may reduce or eliminate overstress experienced by the circuit board 62 and/or the components 64.

At block 192, a component 64 for a circuit board may be identified. The electronic device 10 may include multiple components 64 may couple to a first surface 66A or a second surface 66B of the circuit board 62, respectively. As illustrated, the support structure 60 may interface with the components 64 on the second surface 66B of the circuit board 62. As such, a component 64 on the second surface 66B of the circuit board 62 may be identified. In other instances, the support structure 60 may couple to the first circuit board 62A. As such a component 64 on the first surface 66A of the circuit board 62 may be identified. The stress threshold may be determined based on a type of component 64. For example, each type of component 64 may include a maximum stress threshold. The stress threshold may be stored in a data structure in a database and/or a memory.

At block 194, a shape and/or a size of the component 64 may be determined. For example, a height, a width, and/or a length of the component 64 may be determined by measuring the component 64. In other instances, the size and/or the shape of the component 64 may be determined based on a specification sheet with information about the component 64. Still in other instances, the size and/or the shape of the component 64 may be stored in a data structure, such as a lookup table, in a database or a memory. The stress threshold for the component 64 may be determined based on a size of the component 64. For example, thicker components 64 may include a higher stress threshold in comparison to thinner components 64. In another example, larger components 64 may include a higher stress threshold in comparison to smaller components 64.

At block 196, a location of the component 64 on the circuit board 62 may be determined. The circuit board 62 may include different properties at different locations. The properties of the circuit board 62 may include a flexural strength, a thickness, a stiffness, a flexibility, a bendability, and so on. For example, certain locations of the circuit board 62 may be more flexible than other locations due to a design of the circuit board 62. In another example, thinner locations of the circuit board 62 may be more prone to bending and/or flexing in comparison to thicker locations of the circuit board 62. The stress threshold may be lower in the thinner locations in comparison to the thicker locations. The properties of the circuit board 62 may impact the stress threshold of the component 62. For example, a component 64 positioned at a flexible location of the circuit board 62 may include a lower stress threshold than a component 64 positioned at a stiffer location of the circuit board 62. In another example, a component 64 may be positioned in an interior of the circuit board 62 may include a higher stress threshold in comparison to a component 64 positioned at an edge of the circuit board 62. Still in another example, the circuit board 62 may include cutouts, which may decrease a stress threshold of certain locations proximate to the cutouts. As such, a component 64 may be positioned proximate to a cutout area of the circuit board 62 may include a higher stress threshold in comparison to a component 64 positioned in areas of the circuit board without cutouts.

At block 198, a stress threshold for the component 64 may be determined based on the shape and/or the size of the component 64 and the location of the component 64. The stress threshold of the component 64 may be determined based on a component size, a component thickness, a component type, a component location with respect to the circuit board 62, and so on. For example, thicker components 64 may include a higher stress threshold in comparison to thinner components 64. In another example, a component 64 positioned at a center of the circuit board 62 may include a lower stress threshold in comparison to a component 64 positioned at an edge of the circuit board 62, a thin area of the circuit board 62, or an area of the circuit board 62 prone to bending or flexing. The stress threshold may be determined for each component 64 on the circuit board 62 based on the attributes of the component 64 as well as the component location with respect to the circuit board 62.

At block 200, a support structure 60 may be generated based on the stress threshold. For example, the support structure 60 may include one or more portions that respectively interface with the components 64. The portions may include different properties that may be customized to support the component. For example, the properties of the portion 68 may be determined based on the stress threshold of the component 64 interfacing with the support structure 60. The properties of the portion 68 may be adjusted based on the microstructures 72 within the portion 68, a packing density of the microstructures 72, a material of the portion, and so on. As such, the support structure 60 may be generated with one or more portions 68 that may be customized to support one or more components 64 based on the stress threshold of the component 64.

At block 202, a film may be applied to the circuit board 62, the component 64, and the support structure 60. During a lamination process, for example, a film may be applied to a surface (e.g., first surface 66A, second surface 66B) of the circuit board 62 and a stress may be applied by the film. To reduce an amount of stress applied to the components 64, the support structure 60 may couple to and support the component 64 and the circuit board 62, thereby reducing or eliminating overstress of the component 64. As discussed herein, the manufacturing process may also include hot bar, molding, SMT, and so on. During these manufacturing process, a material and/or heat may be applied to and/or exert a force on a surface of the circuit board 62 that may be transferred to another surface. To reduce or eliminate overstress of the circuit board 62 and/or the components 64, the support structure 60 with modulated portions 68 may couple to a surface of the circuit board 62 and provide support to the circuit board 62 and/or the components 64.

While the process of FIG. 12 is described using process blocks in a specific sequence, it should be understood that the present disclosure contemplates that the described process blocks may be performed in different sequences than the sequence illustrated, and certain described process blocks may be skipped or not performed altogether.

FIG. 130 is a flowchart of an example process 240 for performing a manufacturing process on the circuit board 62 of the electronic device 10 with support from the support structure 60. As discussed herein, the circuit board 62 may undergo a manufacturing process prior to assembly of the electronic device 10. During manufacturing process, a material (e.g., film) may be applied to the circuit board 62 as well as to one or more components 64 coupled to the circuit board 62. The material may exert a force on the circuit board 62 and/or the one or more components 64. To reduce an amount of stress experienced by the circuit board 62 and/or the one or more components 64, a support structure 60 may be coupled to the circuit board 62 and/or the one or more components 64 and absorb an amount of stress and/or distribute an amount of stress exerted by the film. As such, the support structure 60 may reduce an amount of stress experienced by the circuit board 62 and/or the one or more components 64, thereby reducing or eliminating board deformation and/or components 64 cracking during the manufacturing process.

At block 242, a support structure 60 may be coupled to a circuit board 62. For example, an operator may pick and place the support structure 60 onto the circuit board 62 or vice versa. The support structure 60 may couple to a first surface 66A or a second surface 66B of the circuit board 62 and distribute stress exerted onto the circuit board 62. As discussed herein, the support structure 60 may include one or more portions 68 customized to fit a respective component 64 of the circuit board 62 and/or support the respective component 64. For example, the portion 68 may a recession with a height, a width, and/or a length based on the component 64 to receive and/or fit to the component 64. Additionally or alternatively, the portion 68 may include a set of properties customized to the component 64 to provide distribute stress experienced by the component 64 and/or absorb an amount of stress exerted onto the component 64. The support structure 60 may include multiple portions 68 with respective sets of properties customized to a respective component 64 to provide support.

At block 244, a film may be applied to the circuit board 62 and the support structure 60. As discussed herein, a film may be applied to a first surface 66A of the circuit board 62 during the lamination process. The film may exert a stress and/or pressure onto the first surface 66A that may be transferred through the circuit board 62 and to the second surface 66B. As discussed herein, the manufacturing process may also include hot bar, molding, SMT, and so on. During these manufacturing process, a material and/or heat may be applied to and/or exert a force on a surface of the circuit board 62 that may be transferred to another surface. To reduce or eliminate overstress of the circuit board 62 and/or the components 64, the support structure 60 with modulated portions 68 may couple to a surface of the circuit board 62 and provide support to the circuit board 62 and/or the components 64.

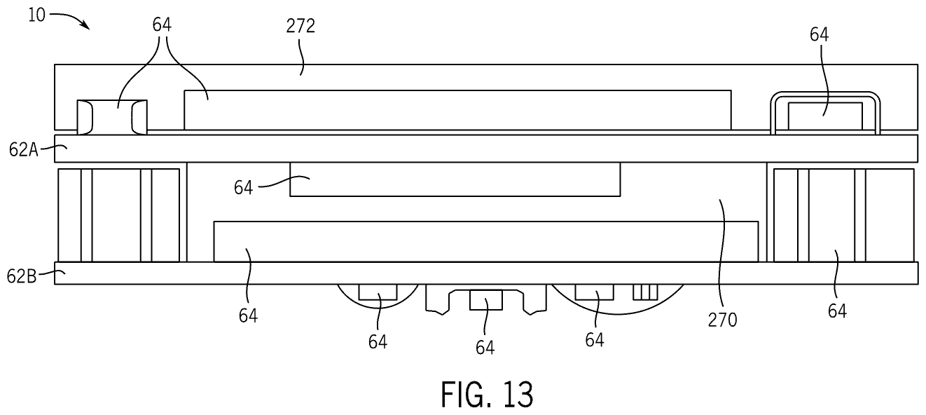

While the process of FIG. 13 is described using process blocks in a specific sequence, it should be understood that the present disclosure contemplates that the described process blocks may be performed in different sequences than the sequence illustrated, and certain described process blocks may be skipped or not performed altogether.

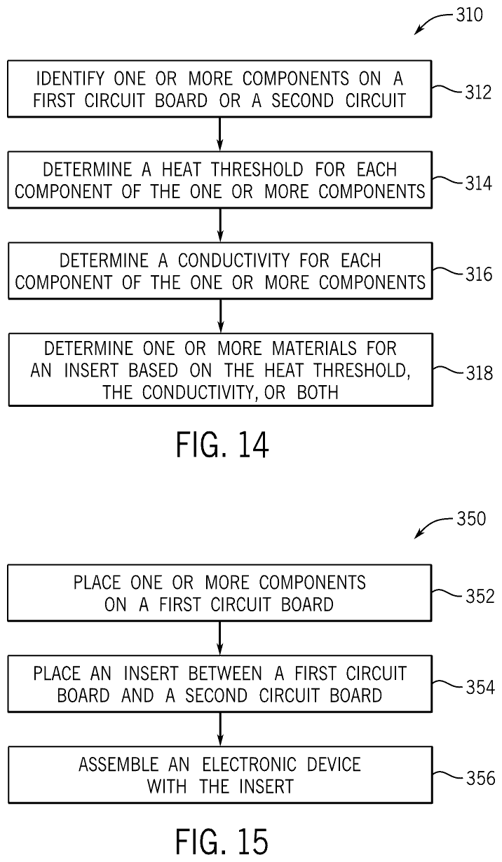

FIG. 14 is a cross-sectional view of the electronic device 10 within the housing 36. The electronic device 10 may include a first circuit board 62A and a second circuit board 62B respectively coupled to one or more components 64. For example, the one or more components 64 may include a system on a chip, a baseband processor, a transistor, a capacitator, a resistor, and so on. As discussed herein, the one or more components 64 may generate heat during operation of the electronic device 10 and/or experience external forces during operation of the electronic device 10. For example, a user may drop the electronic device 10, thereby causing forces to be exerted onto the electronic device 10 and its components. In another example, the user may place the electronic device 10 on a table, which may cause forces to be experienced by the electronic device 10.

To improve operation of the electronic device 10, the electronic device 10 may include an insert 270. As illustrated, the insert 270 may be positioned between the first circuit board 62A and the second circuit board 62B. The insert 270 may dissipate heat from and/or provide support to the circuit boards 62 and/or the one or more components 64 during operation of the electronic device 10.

The insert 270 may be created based on a size and/or a shape of the components 64 interfacing with the insert 270. For example, the insert 270 may couple to the first circuit board 62A via a first surface 272A and couple to the second circuit board 62B via a second surface 272B. A height of the insert 270 may be adjusted (e.g., varied) such that the insert 270 may receive and/or interface with the one or more components 64 coupled to the circuit boards 66. For example, the insert 270 may include a first surface 272A interfacing with the first circuit board 62A and a second surface 272B interfacing with the second circuit board 62B. On the first surface 272A, the insert 270 may include a first recession 274 that receives and/or interfaces with the first component 64A. The first recession 274 may include a height equivalent to a height of the first component 64A to receive and/or interface with the first component 64A. On the second surface 272B, the insert 270 may include a second recession 276 with a height equivalent to a height of the second component 64B to receive and/or interface with the second component 64B. As illustrated, for example, the thickness (e.g., height) of the insert 270 may be varied based on an amount of space between the circuit boards 66 and/or a height of the components 64 extending from the circuit board 66. As such, a size of the insert 270 may be customized to fit the components 64 coupled to the circuit board 62. Additionally or alternatively, a shape of the recessions 272, may be adjusted based on a shape of the component 64. For example, the recessions 272 may be circular, triangular, hexagonal, and the like to receive and/or interface with a respective component 64.

The insert 270 may dissipate heat generated by the one or more components 64. For example, the insert 270 may conduct heat from the one or more components 64 and direct the heat away from the one or more components 64. The insert 270 may include a pattern (e.g., lattice structure) with microstructures oriented in different directions, which may facilitate conducting heat in a first direction and dissipating the heat in a second direction. For example, the pattern may include microstructures oriented in a horizontal direction to absorb heat from the components 64 and microstructures oriented in a vertical direction to direct heat in the vertical direction and/or away from the components 64. Additionally or alternatively, the insert 270 may include conductive materials to conduct heat. The conductive materials may include graphite tubes, alumina oxide, silicon, silicon-based materials, metal particles, copper, and so on. By way of example, the insert 270 may include graphite tubes oriented in vertical direction, conduct the heat from the components 64 and direct the heat in the vertical direction. The insert 270 may couple to both the first component 64A and the second component 64B. The insert 270 may conduct heat generated by the second component 64B and direct the heat vertically through the first component 64A, the first circuit board 62A, and the housing 36. The insert 270 may also include graphite tubes oriented in a horizontal direction, a diagonal direction, and so on. The graphite tubes may direct heat in the direction of orientation. Additionally or alternatively, the insert 270 may include a first portion with graphite tubes oriented in a first direction and a second portion 68B with graphite tubes oriented in a second direction, where the first direction is different from the second direction. In this way, the insert 270 may direct heat away from the components 64 in two different directions.

The insert 270 may provide support to the circuit boards 66 and/or the one or more components 64 by absorbing shock, stress, and/or pressure exerted onto the circuit boards 66. For example, the insert 270 may provide support (e.g., mechanical support) to dissipate shock to the circuit boards 66 and/or the one or more components 64 during a drop. Similar to the support structure 60 described with respect to FIG. 7, the insert 270 may include one or more portions that include respective patterns customized to support a respective component 64. The patterns may include microstructures that may be designed based on the type of component 64 and/or a location of the component 64 on the circuit board 66. For example, the microstructures may be densely packed to provide stiffer support to a component 64 in comparison to microstructures that may be more porous.

In certain instances, the insert 270 may be electrically conductive to transmit signals from a first component 64 to a second component 64. For example, the insert 270 may be made from an electrically conductive material, such as copper, gold, nickel, alloys, graphite, graphene, polymers, and so on. As such, the insert 270 may receive one or more electrical signals from the one or more components 64 and transmit the electrical signals to other components 64.

In other instances, the insert 270 may block signals from being transmitted between the components 64. For example, the insert 270 may be made from a plastic material and/or a ceramic material that may not conduct electricity and/or signals between the components 64. Similar to the support structure 60 described with respect to FIG. 7, the insert 270 may be 3D printed with one or more portions that may include respective properties. The portions may be immediately bonded during the 3D printing process to create a modulated insert 270. As such, the insert 270 may be customized to provide support to each component 64 based on the attributes of the component 64.

Additionally or alternatively, the electronic device 10 may include a top layer 278 and/or a bottom layer 280 that couple to the first circuit board 62A and the second circuit board 62B, respectively. The top layer 278 and/or the bottom layer 280 may be created in a similar manner as the insert 270. For example, the top layer 278 may be disposed between the first circuit board 62A and the housing 36 and the bottom layer 280 may be disposed between the second circuit board 62B and the housing 36. Both the top layer 278 and the bottom layer 280 may include one or more recessions equivalent to a height of the components 64 in order to receive the components 64. The top layer 278 and the bottom layer 280 may be made using a material to conduct heat from the components 64 and direct the heat in a direction. For example, the top layer 278 and/or the bottom layer 280 may include graphite tubes oriented in a direction (e.g., vertical direction) to direct heat through the housing 36 and away from the components 64.

Additionally or alternatively, the top layer 278 an the bottom layer 280 may also provide support to the circuit boards 62. For example, the top layer 278 may absorb an amount of stress exerted onto the electronic device 10 during the drop, thereby reducing an amount of stress experienced by the first circuit board 62A and/or the components 64. Similarly, the bottom layer 280 may absorb an amount of stress exerted onto the electronic device 10 during a drop. The top layer 278 and/or the bottom layer 280 may be modulated to provide support to the circuit boards 62. For example, the top layer 278 and/or the bottom layer 280 may include one or more portions (e.g., the portions 68 described with respect to FIG. 7) with a respective pattern (e.g., pattern 90, pattern 120, pattern 150 described with respect to FIGS. 8-10) that may be determined based on the component 64. For example, the top layer 278 may include three portions to provide support to the three components 64 coupled to the first circuit board 62A and the bottom layer 280 may include three portions to provide support to the three components 64 coupled to the second circuit board 62B. Each portion may include a recession with a size equivalent to a size of the interfacing component. As such, the portion may receive and/or interface with the component 64.

FIG. 15 is a flowchart of an example process 310 for creating an insert 270 for the electronic device 10. For example, the insert 270 may include one or more portions 68 customized to dissipate heat from and/or provide support to respective components 64 interfacing with the portion 68. The properties of each portion 68 may be determined based on a heat threshold of the component 64, the conductivity of the component 64, a size of the component 64, or any combination thereof.

At block 312, one or more components 64 may be identified on a first circuit board 62A or a second circuit board 62B. For example, the circuit board 62 may include one or more components 64 coupled to a first surface 66A of the circuit board 62 and/or a second surface 66B of the circuit board 62.

At block 314, a heat threshold may be determined for each component 64 of the one or more components 64. For example, each component may include a maximum temperature at which the component 64 may operate effectively and/or without experiencing degradation. The heat threshold for each component may 64 may be determined based on a specification sheet, data within a lookup table, or the like. The heat threshold may be determined based on a type of the component 64.

At block 316, a conductivity may be determined for each component 64 of the one or more components 64. For example, thermoconductivity of each component 64 may be determined based on a type of component, a location of the component, and so on. In another example, an electrical conductivity of each component 64 may be determined. In other instances, the electrical resistivity, dielectric constant, stress threshold, and/or thermoconductivity of the component 64 may be determined.

At block 318, one or more materials for an insert 270 may be determined based on the heat threshold, the conductivity, or both. In certain instances, material for a portion 68 of the insert 270 may be determined based on the heat threshold of the component 64, the conductivity of the component 64, or any combination thereof. For example, silicon oxide may be used as a material for the insert 270 due to the components 64 generating a lot of heat and/or signals since silica oxide may be a good heat conductor but a poor electrical conductor. As such, the insert 270 may include a set of properties customized to support the component 64.

Additionally or alternatively, a size and/or a shape of each component 64 may be determined to determine a size and/or a shape of the insert 270. For example, the insert 270 may include one or more recessions that include a size (e.g., height) based on a height of the component 64 in order to receive and/or fit the component 64. In another example, a shape of the recession may be determined based on a shape of the component 64. As such, the insert 270 may couple to and/or support each component 64 of the circuit board 62.

The process of FIG. 15 may be used to create the top layer 278 and/or the bottom layer 280. For example, the top layer 278 may be created by identifying one or more components on a first circuit board (block 312), determining a heat threshold for each component (block 314), determining a conductivity for each component (block 316), and determining a material for the top layer 278 based on the heat threshold, the conductivity, or both (block 318). The bottom layer 280 may be created in a similar manner. In this way, the insert 270, the top layer 278, and/or the bottom layer 280 may provide customized heat transfer and/or support to each component 64 of the electronic device 10.

While the process of FIG. 15 is described using process blocks in a specific sequence, it should be understood that the present disclosure contemplates that the described process blocks may be performed in different sequences than the sequence illustrated, and certain described process blocks may be skipped or not performed altogether.

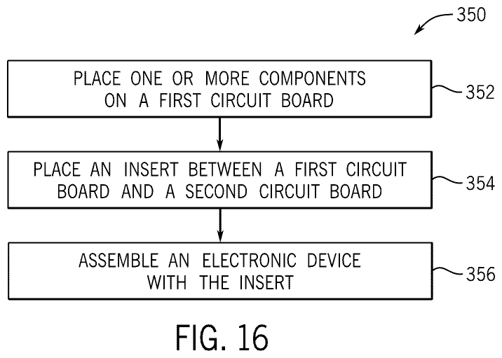

FIG. 16 is a flowchart of an example process 350 for assembling the electronic device 10 with the insert 270. In certain instances, the electronic device 10 may be assembled using a pick and place process. For example, one or more components 64 may be selected by a user and/or a machine and placed onto the circuit board (e.g., the first circuit board 62A, the second circuit board 62B). The circuit board 62 and the components 64 coupled to the circuit board may be coupled to an insert 270. During operation of the electronic device 10, the insert 270 may dissipate heat from and/or structurally support the circuit board 62 and/or the components 64.

At block 352, one or more components 64 may be placed on a first circuit board 62A. For example, a user and/or a machine may select one or more components 64 to place on the first circuit board 62A. The components 64 may be coupled to a first surface of the first circuit board 62A or a second surface of the first circuit board 62A. Additionally or alternatively, the user and/or the machine may determine a respective location for each component 64 on the first circuit board 62A. The location may be determined based on a circuit design, a functionality of the component, a type of the component, a size of the component, and so on. After being placed on the first circuit board 62A, the components 64 may be bonded, and thus, coupled to the first circuit board 62A. Additionally or alternatively, one or more components may be placed and/or coupled to a second circuit board 62B disposed within the housing 36 along with the first circuit board 62A.

At block 354, an insert 270 may be placed between a first circuit board 62A and a second circuit board 62B. For example, an insert 270 may be picked and placed to couple to the first circuit board 62A or the second circuit board 62B. The insert 270 may be positioned between the first circuit board 62AA and the second circuit board 62B to dissipate heat from the components 64 and/or support the components 64 by absorbing stress exerted onto the electronic device 10. As discussed herein, the insert 270 may include multiple portions 68 with properties customized to support a respective component 64 interfacing with a respective portion 68. For example, a first portion 68 of the insert 270 may include a first set of properties to support a first component 64 coupled to the first circuit board 62A and a second portion 68 with a second set of properties to support a second component 64 coupled to the second circuit board 62B. To dissipate heat from the one or more components 64, the insert 270 may be made from a material that conducts heat, such as heat generated by the components 64, and direct the heat in a direction away from the components 64. Additionally or alternatively, the additional inserts (e.g., the layer 278 and the layer 280 described with respect to FIG. 13) may be placed on the first circuit board 62A and the second circuit board 62B, respectively. The additional inserts may dissipate heat and/or structurally support the components 64 on the first circuit board 62A and the second circuit board 62B, respectively.

At block 356, an electronic device 10 may be assembled with the insert 270. For example, the electronic device 10 may include a housing 36 that surrounds one or more interior components, such as the first circuit board 62A, the second circuit board 62B, and/or the insert 270.

While the process of FIG. 16 is described using process blocks in a specific sequence, it should be understood that the present disclosure contemplates that the described process blocks may be performed in different sequences than the sequence illustrated, and certain described process blocks may be skipped or not performed altogether.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An electronic device, comprising:
a first circuit board coupled to a first set of components;
a second circuit board coupled to a second set of components; and
a three-dimensional (3D) printed insert disposed between the first circuit board and the second circuit board.

2. The electronic device of claim 1, wherein the 3D printed insert is configured to direct heat in a horizontal direction or a vertical direction.

3. The electronic device of claim 2, wherein a first lattice structure of a first portion of the 3D printed insert is oriented horizontally and configured to direct the heat in the horizontal direction, and wherein a second lattice structure of a second portion of the 3D printed insert is oriented vertically and configured to direct the heat in the vertical direction.

4. The electronic device of claim 1, wherein the 3D printed insert is configured to couple to the first set of components and the second set of components and absorb heat from both the first set of components and the second set of components.

5. The electronic device of claim 1, wherein the 3D printed insert is configured to support structurally support the first set of components, the second set of components, or both.

6. The electronic device of claim 1, wherein a first portion of the 3D printed insert with a first component of the first set of components comprises a first material and a second portion of the 3D printed insert interfaces with a second component of the second set of components comprises a second material, wherein the first material and the second material are different.

7. The electronic device of claim 6, wherein the first material and the second material are determined based on a thermoconductivity of the first component and the second component, respectively.

8. The electronic device of claim 1, wherein a first portion of the 3D printed insert interfacing with a first component of the first set of components comprises a first lattice shape and a second portion of the 3D printed insert interfacing with a second component of the second set of components comprises a second lattice shape, wherein the first lattice shape and the second lattice shape are different.

9. The electronic device of claim 1, wherein a first component of the first set of components is shorter than a second component of the first set of components, and wherein a height of a first portion of the 3D printed insert interfacing with the first component is greater than a height of a second portion of the 3D printed insert interfacing with the second component.

10. The electronic device of claim 1, comprising another 3D printed insert configured to couple to the second circuit board and a housing of the electronic device, wherein the other 3D printed insert comprises graphite.

11. A system, comprising:
a circuit board coupled to a set of components; and
a 3D support structure coupled to the circuit board and configured to mechanically support the circuit board during a manufacturing operation.

12. The system of claim 11, wherein a first portion of the 3D support structure interfacing with a first component of the set of components comprises a first material and a second portion of the 3D support structure interfacing with a second component of the set of components comprises a second material, wherein the first material and the second material are different.

13. The system of claim 12, wherein the first material is based on a location of the first component on the circuit board.

14. The system of claim 12, wherein the first material and the second material vary based on a stress threshold of the first component and the second component, respectively.

15. The system of claim 12, wherein a first lattice structure of the first portion of the 3D support structure is based on a location of the first component on the circuit board.

16. The system of claim 15, wherein a second lattice structure of the second portion of the 3D support structure is different from the first lattice structure.

17. The system of claim 11, comprising a carrier configured to couple to the 3D support structure.

18. A method, comprising:
receiving a circuit board;
providing a three-dimensional (3D) printed support structure around a plurality of components on a first side of the circuit board; and
performing operations to the circuit board and the 3D printed support structure, wherein the 3D printed support structure supports the circuit board.

19. The method of claim 18, wherein the 3D printed support structure comprises a plurality of modulated portions, wherein each modulated portion is configured to interface with a component of the plurality of components on the first side of the circuit board.

20. The method claim 18, comprising designing a 3D printed insert based on respective properties of the plurality of components.

21. The method of claim 20, comprising assembling a mobile device using the plurality of components, the circuit board, and the 3D printed insert.
